(19) United States
(12) Patent Application Publication
(10) Pub. No.: US 2008/0173538 A1
(43) Pub. Date: Jul. 24, 2008

(54) Method and apparatus for sputtering

(76) Inventors: Sun-Oo Kim, Hopewell Junction, NY (US); Bum Ki Moon, LaGrangeville, NY (US); Erdom Kaltalioglu, Newburgh, NY (US)

Correspondence Address: SLATER & MATSIL LLP, 17950 PRESTON ROAD, SUITE 1000, DALLAS, TX, 75252, US

(21) Appl. No.: 11/655,488

(22) Filed: Jan. 19, 2007

(51) Int. Cl. C23C 14/34

(52) U.S. Cl. 204/192.32; 204/192.1; 204/298.01

(57) ABSTRACT

A sputtering apparatus includes a target electrode and a bias source electrically coupled to the target electrode. A wafer chuck is spaced from the target electrode. The wafer chuck is partitioned into a plurality of zones, each zone being coupled to receive an AC signal having an amplitude that can vary by zone. At least one RF coil is positioned adjacent a space between the target electrode and the wafer chuck.

### TECHNICAL FIELD

The present invention relates generally to semiconductor devices and methods, and more particularly, to a metal interconnect structure and method.

### BACKGROUND

Semiconductors are widely used for integrated circuits for electronic applications, including radios, televisions, and personal computing devices, as examples. Such integrated circuits typically use multiple transistors fabricated in single crystal silicon. It is common for there to be millions of semiconductor devices on a single semiconductor product. To provide the necessary signal and power interconnections for the multiplicity of semiconductor devices, many integrated circuits now include multiple levels of metallization.

The semiconductor industry continuously strives to decrease the size of the semiconductor devices located on integrated circuits. Miniaturization is generally needed to accommodate the increasing density of the circuits necessary for today's advanced semiconductor products. The increasing density has led to the need for more metallic layers, typically of aluminum and more recently of copper, to provide the circuit interconnections. For CMOS ICs with 250 nm feature size, four metallic layers for interconnections were sufficient. Below 100 nm, nine or more metallic layers are often used. With the increasing number of metallic interconnection layers, more manufacturing steps and cost are required to form the interconnections than the transistors and other semiconductor components in the semiconductor device. For high complexity, high density chips with six or more layers of metallization, the total length of the layered interconnect wiring in the chip can be of the order of a mile. The signaling speed among on-chip devices provided by these interconnections has become a significant factor in chip performance. The resistance of the interconnecting wiring generally increases as a consequence of its width-height product being reduced faster than its length is shortened, which further aggravates the signaling-speed problem.

One solution to the problem of line resistance is by using copper interconnects. While copper has the desirable property of low resistivity, it has the problem of being difficult to etch as well as having the propensity of drifting and diffusing into any surrounding interlevel dielectric exposed to the surface of the copper.

To address the issue of copper being difficult to etch, a layered and patterned metal interconnect structure is conventionally formed in the upper layers of an integrated circuit to provide the necessary circuit connections for the various semiconductor devices in the integrated circuit such as transistors and diodes. In high-density integrated circuits, damascene techniques are used to form and deposit metal lines and vias for the desired interconnections in a surrounding dielectric layer.

In ordinary damascene processes, trenches and vias are patterned and dry-etched during BEOL processing (“back end of line” processing, which is the processing performed after the first metallic contacts are formed on the die), typically to a depth of about 0.2 to 0.5 μm, in a dielectric layer using lithographic techniques. A trench and/or a via is first lined with a thin liner material such as tantalum, and then entirely filled with a metal, preferably copper in advanced processes. Excess metal deposited outside the trench is removed by a CMP (chemical-mechanical polishing) process, leaving a clean metal line or via substantially planarized with the surrounding dielectric. The via- and trench-forming steps are repeated to produce a number of layers of interconnected metallic lines for the underlying semiconductor devices.

### SUMMARY OF THE INVENTION

In one embodiment, a sputtering apparatus comprises a target electrode, a bias source electrically coupled to the target electrode, a wafer chuck situated beneath the target electrode, the wafer chuck comprising a perimeter, a substantially flat surface and plurality of electrodes, and a plurality of RF coils positioned at or beyond the perimeter of the wafer chuck between the target electrode and the wafer.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional sputtering apparatus;

FIGS. 2a-2b illustrate a sputtering apparatus of one embodiment of the present invention;

FIG. 3 contains a functional diagrams of a sputtering apparatus of the invention;

FIGS. 4a-4b illustrate a sputtering apparatus of one embodiment of the present invention;

FIG. 5 contains a functional diagram of a sputtering apparatus of the invention; and

FIGS. 6a-6f contain cross-sectional views of the fabrication of a the barrier layer and copper interconnect in a damascene trench and via;

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION

The making and using of the presently preferred embodiments are discussed in detail below. It should be appreciated, however, that the invention provides many applicable inventive concepts that can be embodied in a wide variety of specific contexts. The specific embodiments discussed are merely illustrative of specific ways to make and use the invention, and do not limit the scope of the invention.

The invention will be described with respect to preferred embodiments in a specific context, namely a method and apparatus for reverse sputtering to back etch a liner for a copper interconnect structure. The invention may also be applied, however, to other semiconductor structures.

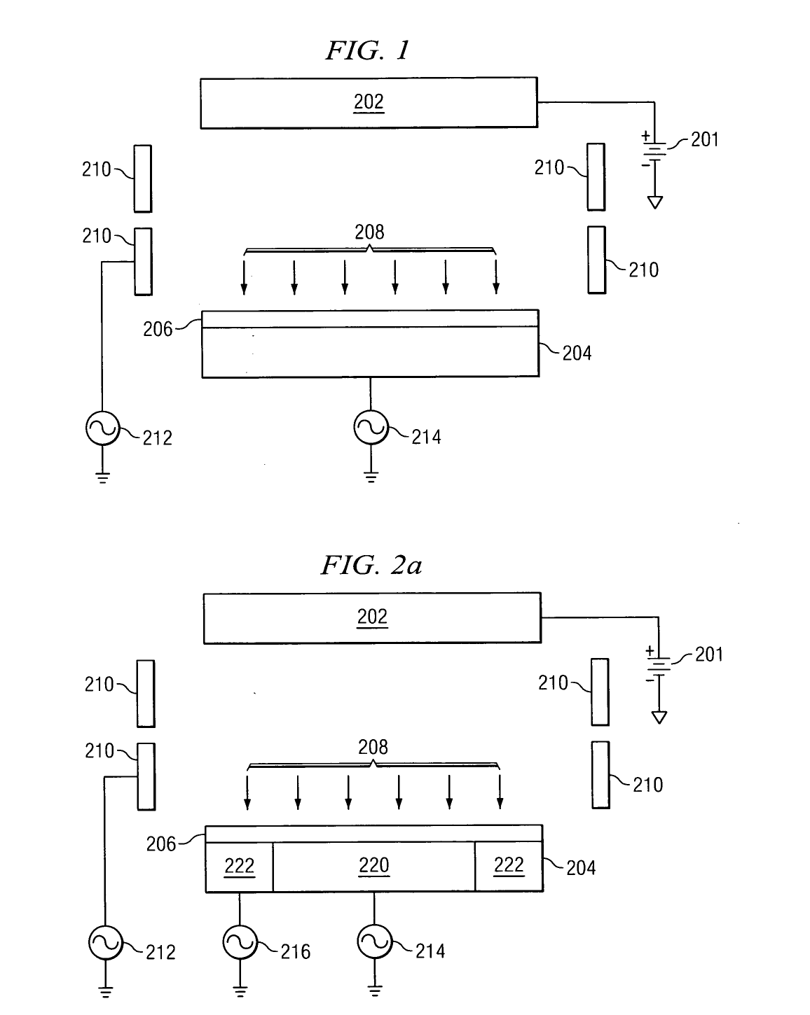

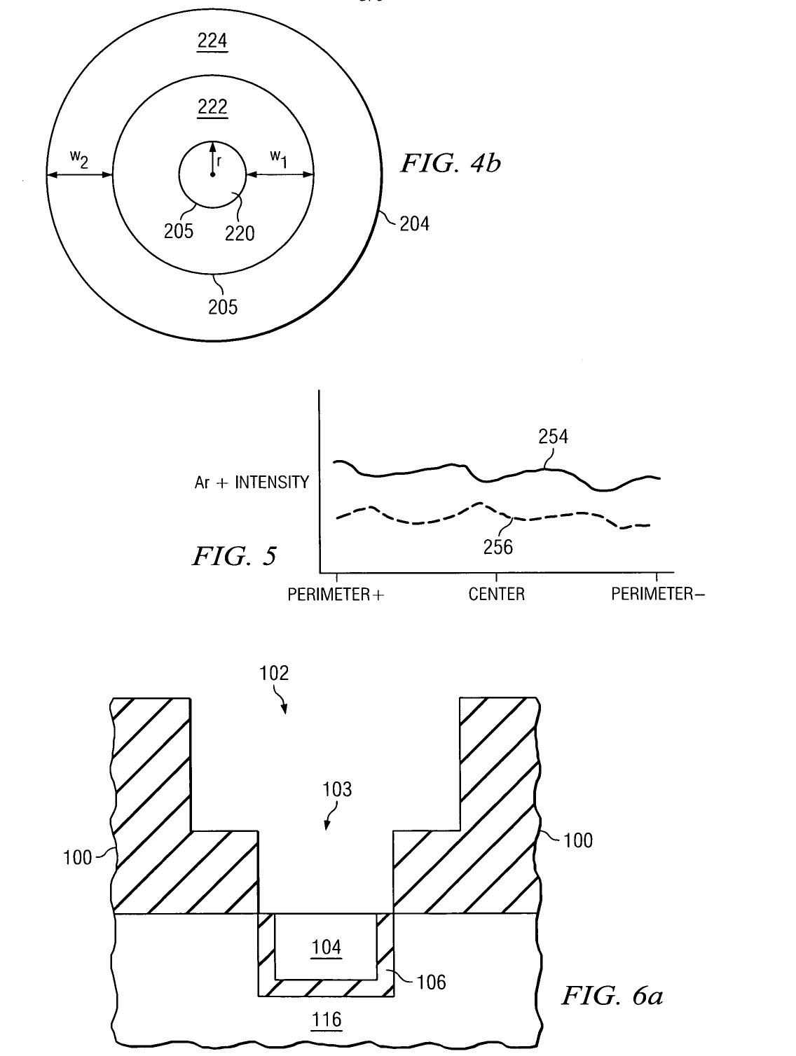

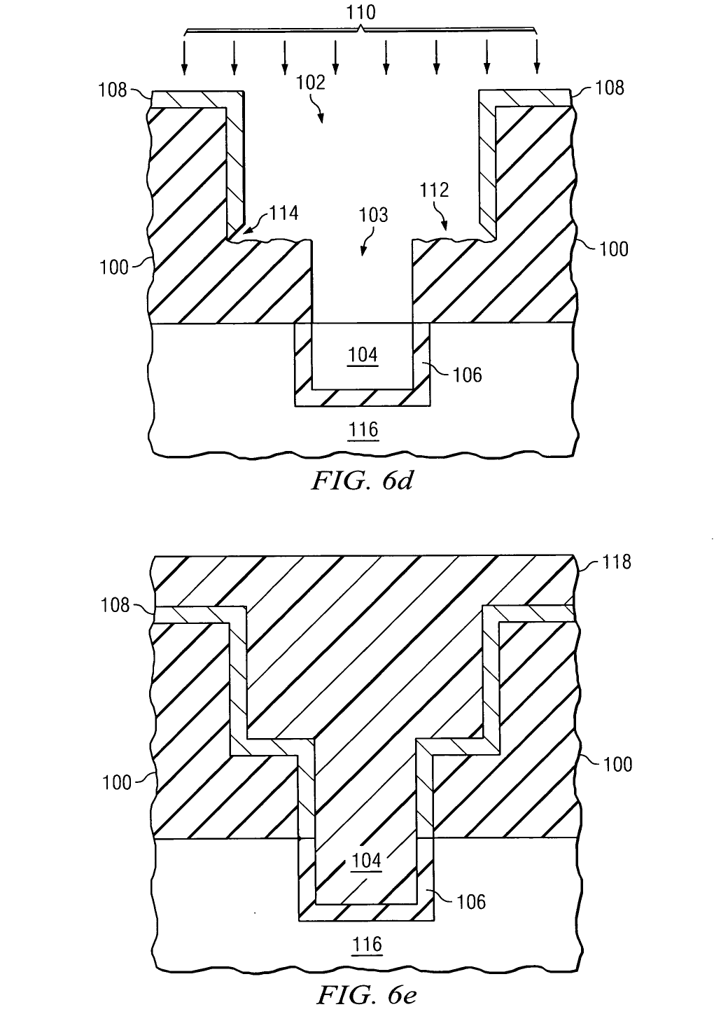

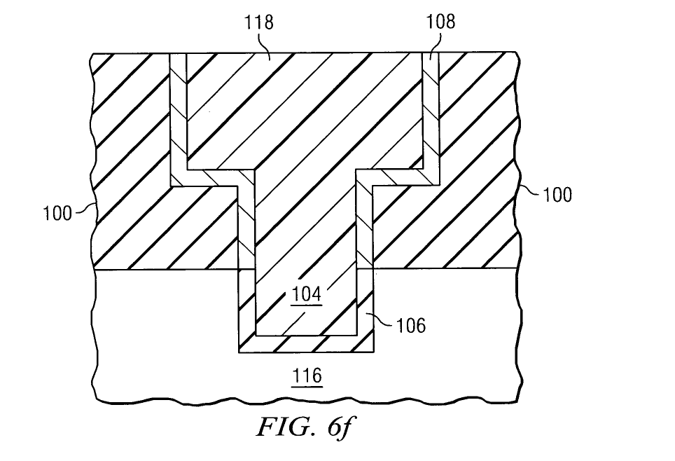

Various embodiments of a manufacturing apparatus that incorporates features of the present invention will now be discussed with respect to FIGS. 1, 2a-2b and 4a-4b. FIGS. 3 and 5 illustrate the operation of these devices. Finally, a method of manufacturing a semiconductor device using the apparatus will be described with respect to FIGS. 6a-6d.

FIG. 1 shows a representative diagram of a conventional apparatus used to perform etch-back processing within a vacuum chamber (not shown). In this system, a wafer 206 will be processed. The wafer 206 is mounted on a chuck 204. An RF plasma is generated between the chuck 204 and a target 202.

A DC bias, typically between 100 V and 100 kV, is applied to the target 202 in order to ionize gas, e.g., argon gas, introduced into the vacuum chamber. RF coils 210, to which a 13.56 MHz source 212 is typically connected, orient the argon ions 208 so that they achieve a vertical directionality. An RF source 214 is coupled to the chuck 204. The RF source 214 attached to the chuck 204 is a plasma generating source, while the source 212 attached to the coils 210 is used to steer the argon ions.

When a single source 214 is attached to the chuck 214, the distribution of argon across the wafer tends to be unevenly distributed, as illustrated by line 250 of FIG. 3. The ionized argon distribution is higher along the perimeter of the wafer and lower in the center of the wafer. If the process is optimized so that the center of the wafer has the highest yield, the perimeter of the wafer will be exposed to a higher argon ion concentration, thereby causing the perimeter of the wafer to be overetched.

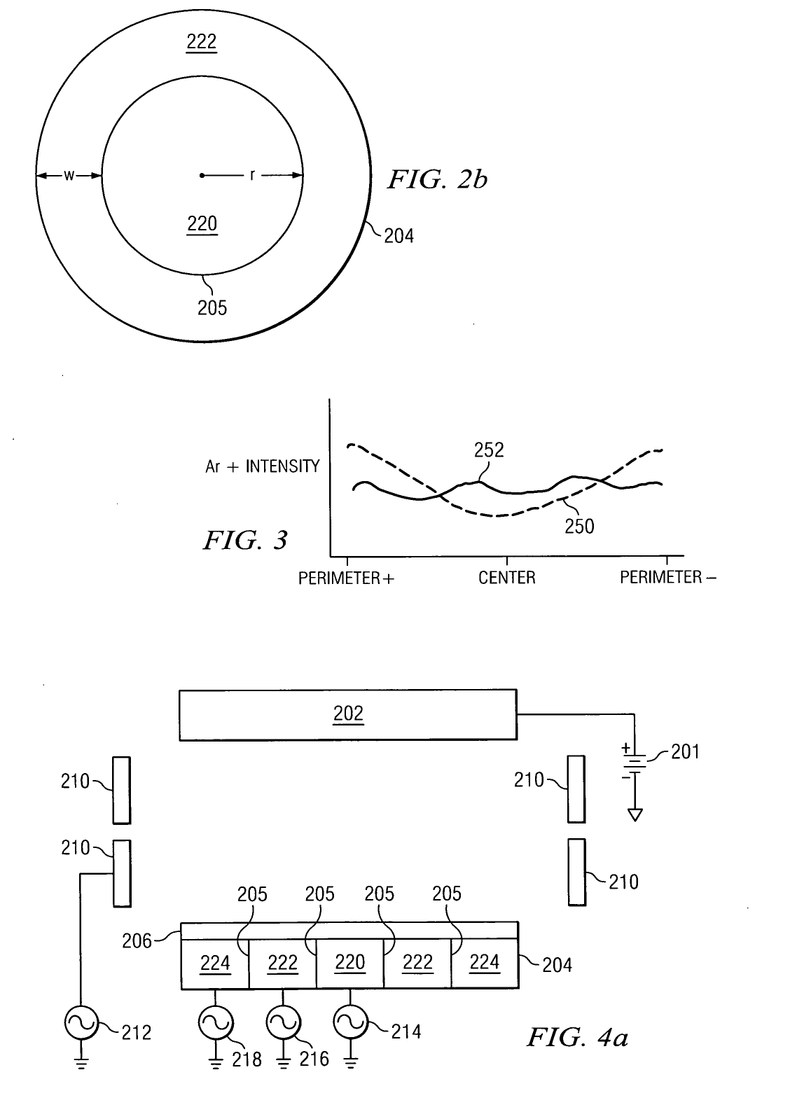

In one embodiment of the present invention, which is illustrated in FIG. 2a, wafer chuck 204 is divided into two zones; an inner zone 220, and an outer zone 222. Typically, each zone is connected to RF signals 214 and 216 of differing amplitudes. In some embodiments, separate sources can be used. In other embodiments, attenuators and phase shifters can be used to create the different amplitude levels.

FIG. 2b shows a top view of the wafer chuck. In this example, the inner zone 220 comprises a circular region of the wafer chuck 204 while the outer zone 222 comprises an annular region that surrounds the inner zone 220. In one embodiment, the radius r of the inner zone 220 is between about 75 mm and about 125 mm and the width w of the outer zone 222 is between about 75 mm and about 125 mm. These values generally apply to 200 mm and 300 mm wafers, but may be applicable to other wafer diameters, especially larger diameters. It is understood that wafers of differing sizes would require a chuck proportioned accordingly. In typical embodiments the ratio of the radius r to the width w (r:w) is about 0.5 to about 2. In other embodiments, however, these dimensions and ratios may be outside of the ranges stated herein.

Inner zone 220 is separated from outer zone 222 by an insulating region 205. In embodiments of the present invention, insulating region 205 may consist of a physical gap or an insulating material. In embodiments of the present invention, the wafer chuck 204 is formed from a conductive material such as AlN or other conductive materials.

Turning to FIG. 3, curve 252 represents the argon ion intensity across the wafer when embodiment of FIG. 2 is implemented and when the RF signal levels are optimized to achieve uniform intensity and uniform wafer coverage. In a preferred embodiment of the present invention, less bias would be applied to outer zone 222 than to inner zone 220 so that the perimeter of the wafer does not experience peak levels of argon ions. For example, the peaks seen at the endpoints of curve 250 can be eliminated as seen on curve 252. In a typical application, the amplitude of the signal applied to the outer zone 222 would be about 50% to about 200% of the amplitude applied to the inner zone 220.

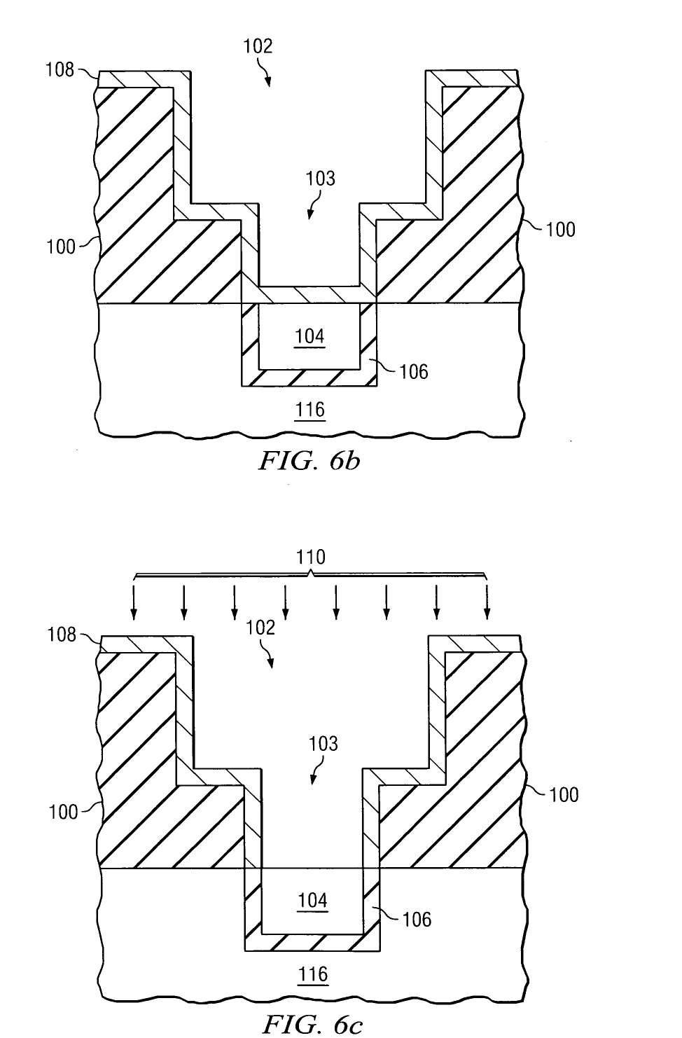

The uniformity of the argon intensity can be further improved by adding additional zones. To illustrate this point, an additional embodiment of the present invention is shown in FIG. 4a. In this case, the wafer chuck 204 includes three conductive zones 220, 222 and 224. Each conductive zone is separated from each other by an insulating region 205.

FIG. 4b shows a top view of the wafer chuck. In this embodiment, the inner zone 220 is a circular region, the middle zone 224 is a first annular region surrounding the inner zone and the outer zone 222 is a second annular region surrounding the middle zone (and the inner zone). In one embodiment which is designed for a 300 mm wafer 206, the radius r of the inner zone 220 is between about 60 mm and about 100 mm, width w₁ of the middle zone 224 is between about 60 mm and about 100 mm and the width w₂ of the outer zone 222 is between about 60 mm and about 100 mm. Once again, wafers of differing sizes would require a chuck proportioned accordingly.

The uniformity of the argon intensity across the wafer can be further improved as shown in the graph in FIG. 5. Curve 256 is the resultant argon intensity across the wafer if three zones are used. Curve 254 is a reverse profile which shows the feasibility to control the intensity by changing the relative power portion for each part.

In other embodiments, more zones can be included. For example, one embodiment can include two inner zones and another embodiment three or more inner zones. In theory, there is no limit to the number of concentric zones that are included.

In each of the embodiments discussed to this point, the zones have been arranged concentrically around one another. This configuration is not a requirement. For example, the zones can be arranged radially adjacent to one another (like slices of a pie). Further, a combination of concentric rings and radially adjacent “slices” can be implemented.

In other embodiments of the present invention, other material besides argon, such as N₂ or a mixture of N₂ and Ar gases can be used to perform a reverse etch. In yet other embodiments of the present invention, the sputtering apparatus described herein can also be used in sputtering material onto a semiconductor wafer.

FIGS. 6a-6d illustrates one process that can be implemented in the apparatus of the present invention. In the embodiment of FIG. 6, a metal interconnect will be formed over a semiconductor substrate. The sputtering apparatus can also be used in other processes such as cleaning and removal of materials in other processes such as shallow trench isolation (STI) formation.

Referring first to FIG. 6a, a dielectric region 100 overlies a partially fabricated semiconductor wafer 116, which includes a region to be coupled such as a metal line 104. In this illustration, a barrier layer 106 surrounds the bottom and sidewalls of metal line 104. The wafer 116 can include active circuitry electrically coupled to metal line 104 through a number of interconnects, which are not shown. The metal line 104 can be any level of metal (or alternatively are provided into which a trench 102 and via 103 are etched (FIG. 6a).

A dielectric layer 100 is formed over the wafer 116. The dielectric layer 100 can be any interlevel dielectric such as silicon dioxide or doped glass, e.g., borophosphosilicate glass (BPSG) or fluorinated silicate glass (FSG). Alternatively, a porous low-k material can be used for the dielectric layer.

A recess is formed in the dielectric layer 100. In this particular example, a dual damascene process is being implemented so that the recess will include contact hole or via 103 and trench 102. The recess can be formed using either a trench first or via first process. In a single damascene process the contact hole or via 103 would be formed first, followed by formation of the trench 102. For example, in a single damascene process the trench 102 would expose a conductor within the via 103.

Referring next to FIG. 6b, a barrier layer 108 is formed along sidewalls and bottom surfaces of the trench 102 and via 103. This barrier typically contains a material such as tantalum and is deposited on the dielectric 100, trench 102, via 103, and the top portion of the metal line 104. In one example, a tantalum nitride barrier is deposited.

In order to keep the resistance of the via 103 low, the bottom portion of via 103 is etched back as shown in FIG. 6c. The etching is typically done using reverse biased sputtering using argon gas. This reverse bias sputtering process can be performed in a sputtering apparatus as described above.

One problem that can be solved by various embodiments of the invention is illustrated in FIG. 6d. This figure illustrates the situation where the sputtering process “overetches” the barrier layer 108. This overetch can expose portions 112 of the dielectric material 100 along sidewalls of the via 103 and/or the bottom of the trench 102. This removal of material will cause unwanted contact between the fill material (not shown) and the dielectric, which will lead to quality and reliability issues for the devices.

By adjusting parameters related to the sputtering along various portions of the wafer, this overetch can be avoided. For example, as discussed above, peripheral portions are more likely to be overetched and experience defects as shown in FIG. 6d. These defects can be avoided by tailoring the RF signals applied to portions of the chuck near these portions.

Turning to FIG. 6e, after the barrier 108 has been removed from over region 104, the trench 102 and via 103 can be filled with a conductive material 118, such as copper. In this process, a layer of copper 118 can be deposited over the wafer so as to fill the recess and overlie the top surface of the dielectric 100. A planarization process, such as a chemical-mechanical polish (CMP), can then be performed to remove any conductor 118 from over the wafer surface and leave the remaining conductor 118 in the trench 102 and via 103, as shown in FIG. 6f.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A sputtering apparatus comprising:
a target electrode;
a bias source electrically coupled to the target electrode;
a wafer chuck spaced from the target electrode, the wafer chuck being partitioned into a plurality of zones, each zone being coupled to receive an AC signal having an amplitude that can vary by zone; and
at least one RF coil positioned adjacent a space between the target electrode and the wafer chuck.

2. The sputtering apparatus of claim 1, further comprising at least one RF generation source coupled to the wafer chuck to provide the AC signal to the plurality of zones.

3. The sputtering apparatus of claim 2, wherein the AC signal has a frequency of 13.6 MHz.

4. The sputtering apparatus of claim 2, wherein the at least one RF generation source comprises a plurality of RF generation sources.

5. The sputtering apparatus of claim 1, wherein the wafer chuck is partitioned into at least a first zone and a second zone, the first zone comprising a circular region and the second zone comprising an annular region surrounding the first zone.

6. The sputtering apparatus of claim 5, wherein the wafer chuck is partitioned into at least the first zone, the second zone and a third zone, the third zone comprising an annular region surrounding the first and second zones.

7. The sputtering apparatus of claim 1, further comprising a vacuum chamber, the target electrode, the wafer chuck and the at least one RF coil being housed in the vacuum chamber.

8. The sputtering apparatus of claim 7, further comprising a gas source with an inlet within the vacuum chamber.

9. The sputtering apparatus of claim 8, wherein the gas source comprises an argon gas source.

10. A method of performing a sputtering process, the method comprising:
affixing a workpiece onto a chuck in a sputtering chamber;
introducing a sputtering gas in the sputtering chamber;
ionizing the sputtering gas with a target electrode and a plurality of electrodes situated on the chuck beneath the semiconductor wafer, each one of the plurality of electrodes biased with an independent bias signal; and
directing the ionized sputtering gas toward the semiconductor wafer.

11. The method of claim 10, wherein the independent bias signals are selected so that the ionized sputtering gas has an intensity that is optimized for uniform sputtering across the workpiece.

12. The method of claim 10, wherein the independent bias signals each have a frequency of 13.6 MHz.

13. The method of claim 10, wherein the electrodes include a circular electrode adjacent a center portion of the workpiece and an annular electrode surrounding the circular electrode and adjacent a peripheral portion of the workpiece, the circular electrode being electrically isolated from the annular electrode.

14. The method of claim 13, wherein the circular electrode is biased with a first bias signal and the annular electrode is biased with a second bias signal, the second bias signal having a lower amplitude than the first bias signal.

15. The method of claim 13, wherein the electrodes further include a second annular electrode between the circular electrode and the annular electrode.

16. The method of claim 10, wherein the workpiece comprises a semiconductor wafer.

17. The method of claim 16, wherein the semiconductor wafer comprises:
a semiconductor body;
an insulating layer disposed over the semiconductor body, the insulating layer including a plurality of recesses formed therein; and
a barrier layer lining walls of the recesses.

18. The method of claim 10, wherein the sputtering gas comprises argon.

19. A method of sputter etching a material from a semiconductor wafer, the method comprising:
providing a vacuum chamber;
providing a sputtering material inside the vacuum chamber;
affixing a semiconductor wafer to a wafer chuck inside the vacuum chamber; and
creating a plasma comprising the sputtering material inside the vacuum chamber;
accelerating the sputtering material by creating a potential difference between a target electrode and a plurality of electrodes situated adjacent the wafer chuck beneath the semiconductor wafer, each of one of the plurality of electrodes biased independently.

20. The method of claim 1, further comprising adjusting the independently biased wafer chuck electrodes so that the sputtering material is optimized for uniformity-across the wafer.

21. The method of claim 20, wherein the material to be sputtered is argon.

22. A method of manufacturing a semiconductor device, the method comprising:
forming a dielectric layer over a semiconductor wafer;
forming a plurality of recesses in the dielectric layer;
lining sidewall surfaces and a bottom surface of each of the recesses with a liner;
sputter etching the liner from the bottom surface of each of the recesses, the sputter etching being performed by generating a potential between a plurality of chuck electrodes located beneath the semiconductor wafer and a target electrode spaced above the semiconductor wafer, each of the chuck electrodes being biased with an independent bias signal; and
filling the recesses with a conductive material.

23. The method of claim 22, wherein sputter etching the liner comprises bombarding the semiconductor wafer with argon ions, wherein the liner at the bottom surface of the recess is etched away without etching away any other portion of the liner, regardless of how close to a perimeter of the semiconductor wafer the recess is located.

24. The method of claim 22, wherein the chuck electrodes include a circular electrode adjacent a center portion of the workpiece and an annular electrode surrounding the circular electrode and adjacent a peripheral portion of the workpiece, the circular electrode being electrically isolated from the annular electrode.

25. The method of claim 24, wherein the circular electrode is biased with a first bias signal and the annular electrode is biased with a second bias signal, the second bias signal having a lower amplitude than the first bias signal.

26. The method of claim 24, wherein the electrodes further include a second annular electrode between the circular electrode and the annular electrode.
